(19) United States
(12) Patent Application Publication
(10) Pub. No.: US 2026/0023129 A1
(43) Pub. Date: Jan. 22, 2026

(54) BATTERY OPERATION

(71) Applicant: Analog Devices International Unlimited Company, Limerick (IE)

(72) Inventor: Claire Nelia LEVEUGLE, Killabullen (IE)

(21) Appl. No.: 19/346,981

(22) Filed: Oct. 1, 2025

Related U.S. Application Data
(63) Continuation of application No. 18/789,088, filed on Jul. 30, 2024.
(60) Provisional application No. 63/520,464, filed on Aug. 18, 2023.
(60) Provisional application No. 63/650,587, filed on May 22, 2024.
(60) Provisional application No. 63/665,573, filed on Jun. 28, 2024.
(60) Provisional application No. 63/702,917, filed on Oct. 3, 2024.

(51) Int. Cl. G01R 31/389; G01R 31/367; G01R 31/396; H01M 10/42; H01M 10/44; H01M 10/48

(52) U.S. Cl. CPC G01R 31/389; G01R 31/367; G01R 31/396; H01M 10/425; H01M 10/441; H01M 10/482

(57) ABSTRACT

Examples of the computer-implemented technology disclosed herein establish limits for at least one component of complex impedance for each of a plurality of cells of a battery of a battery type at each of at least one frequency, thereby establishing a safe operating area for the battery within the limits. Such examples measure the at least one component of complex impedance of each of at least one cell of a given battery of the battery type. Such examples compare the measured at least one component of complex impedance to the limits. Such examples manage operation of the given battery based on the comparison.

### CROSS-REFERENCE TO RELATED APPLICATIONS

This application claims the benefit of U.S. Provisional Pat. App. No. 63/702,917 filed Oct. 3, 2024. This application claims priority as a continuation-in-part (CIP) to pending U.S. patent application Ser. No. 18/789,088, filed Jul. 30, 2024; which claims the benefit of U.S. Provisional Pat. App. No. 63/520,464 filed Aug. 18, 2023, U.S. Provisional Pat. App. No. 63/650,587 filed May 22, 2024, and U.S. Provisional Pat. App. No. 63/665,573 filed Jun. 28, 2024. The disclosures of each application mentioned above are hereby incorporated herein in their entirety.

### FIELD OF THE DISCLOSURE

This disclosure relates to battery system operation, generally. More specifically, some examples describes technology for the use of Electrochemical impedance spectroscopy (EIS) in battery operation.

### BACKGROUND

EIS can be used to characterize electrochemical systems such as single cells, batteries comprising one or more cells, and battery assemblies (including measurement and control equipment). EIS can measure the complex impedance of one or more cells over a range of frequencies-using the measurements to characterize, inter alia, energy state, storage, and dissipation properties of the cell(s), battery, or battery assembly. The data obtained through EIS can be represented in Bode plots or Nyquist plots.

The complex impedance includes a real/resistive component and an imaginary/reactive component. Such complex impedance can be measured as a universal dielectric response, whereby EIS reveals a power law relationship between the impedance and the frequency ω of an applied alternating current (AC) forcing function across a range of frequencies. Such current may be applied using a pair of force wires, and the impedance may be measured using at least one set of sense wires, often one pair of sense wires across each cell. The converse approach to measuring impedance can also be used, i.e., a voltage can be forced, and a resulting current can be observed.

### SUMMARY OF THE DISCLOSURE

In some aspects, the techniques described herein relate to a computer-implemented battery management method, including: establishing, by one or more computers, limits for at least one component of complex impedance for each of a plurality of cells of a battery of a battery type at each of at least one frequency, thereby establishing a safe operating area for the battery within the limits; measuring, by the one or more computers, the at least one component of complex impedance of each of at least one cell of a given battery of the battery type; comparing, by the one or more computers, the measured at least one component of complex impedance to the limits; and managing, by the one or more computers, operation of the given battery based on the comparison.

In some aspects, the techniques described herein relate to a battery management system including: a processor; and a memory storing instructions that, when executed by the processor, cause the processor to: establish limits for at least one component of complex impedance for each of a plurality of cells of a battery at each of at least one frequency, thereby establishing a safe operating area for the battery within the limits; measure the at least one component of complex impedance of each of at least one cell of a given battery; compare the measured at least one component of complex impedance to the limits; and manage operation of the given battery based on the comparison.

In some aspects, the techniques described herein relate to a non-transitory computer-readable medium storing instructions that, when executed by a processor, cause the processor to: establish limits for at least one component of complex impedance for each of a plurality of cells of a battery at each of at least one frequency, thereby establishing a safe operating arca for the battery within the limits; measure the at least one component of complex impedance of each of at least one cell of a given battery; compare the measured at least one component of complex impedance to the limits; and manage operation of the given battery based on the comparison.

In some aspects, the techniques described herein relate to a battery system including: a battery including a plurality of cells; a measurement circuit configured to measure at least one component of complex impedance of each of at least one cell of the battery at each of at least one frequency; and a controller configured to: establish limits for the at least one component of complex impedance for each of the plurality of cells at each of the at least one frequency, thereby establishing a safe operating area for the battery within the limits; compare the measured at least one component of complex impedance to the limits; and manage operation of the battery based on the comparison.

### BRIEF DESCRIPTION OF THE DRAWINGS

The present technology will now be described in more detail with reference to the accompanying drawings, which are not intended to be limiting.

FIG. 1 illustrates the concept of safe operating area (SOA) for a battery, in accordance with examples of the technology disclosed herein.

FIG. 2 illustrates a Nyquist plot of cell complex impedance related to the product of voltage and temperature, in accordance with examples of the technology disclosed herein.

FIG. 3 illustrates a plot of each component of complex impedance versus current load for high V*T, low V*T at 12 Hz, in accordance with examples of the technology disclosed herein.

FIG. 4 illustrates a plot of each component of complex impedance versus current load for high V*T, low V*T at 500 Hz, in accordance with examples of the technology disclosed herein.

FIG. 5 illustrates a Nyquist plot of cell complex impedance related to the quotient of voltage and temperature, in accordance with a first example.

FIG. 6 illustrates a plot of each component of complex impedance versus current load for high V/T, low V/T at 12 Hz, in accordance with examples of the technology disclosed herein.

FIG. 7 illustrates a plot of each component of complex impedance versus current load for high V/T, low V/T at 500 Hz, in accordance with examples of the technology disclosed herein.

FIG. 8 illustrates methods of battery operation, in accordance with examples of the technology disclosed herein.

FIG. 9 illustrates methods of battery operation, in accordance with examples of the technology disclosed herein.

FIG. 10 illustrates methods of battery operation, in accordance with examples of the technology disclosed herein.

FIG. 11 schematically illustrates a device that may serve as a computer/processor, in accordance with examples of the technology disclosed herein.

### DETAILED DESCRIPTION

In the following detailed description, reference is made to the accompanying drawings which form a part hereof wherein like numerals designate like parts throughout, and in which is shown by way of illustration examples that may be practiced. It is to be understood that other examples may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described example. Various additional operations may be performed and/or described operations may be omitted in additional examples.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Various components may be referred to or illustrated herein in the singular (e.g., a “processor,” a “peripheral device,” etc.), but this is simply for ease of discussion, and any element referred to in the singular may include multiple such elements in accordance with the teachings herein.

The description uses the phrases “in an example” or “in examples,” which may each refer to one or more of the same or different examples. Furthermore, the terms “comprising,” “including,” “having,” and the like, as used with respect to examples of the present disclosure, are synonymous. As used herein, the term “circuitry” may refer to, be part of, or include an application-specific integrated circuit (ASIC), an electronic circuit, and optical circuit, a processor (shared, dedicated, or group), and/or memory (shared, dedicated, or group) that execute one or more software or firmware programs, a combinational logic circuit, and/or other suitable hardware that provide the described functionality.

Electrochemical systems include both galvanic and electrolytic electrochemical systems such as vehicle batteries, fuel cells, electrochemical capacitors, bio-electrochemical systems, electrochemical sensors, corrosion cells, photo chemical cells, thermos-galvanic cells, and electrochromic system, and can be individual cells or batteries of cells. The technology disclosed herein, while illustrated with respect to galvanic batteries of one or more cells, applies to electrochemical systems in general.

EIS can be used as a tool for generating insights into battery operation in systems such as electric vehicles (EVs), energy storage systems, and various consumer systems. For the purposes of this disclosure, a battery assembly includes: a battery, sensor(s) used to sense a parameter of the battery and/or its component(s), processor(s) in communication with memory storing instructions executable by the processor(s) to practice examples of the technology disclosed herein; and wiring connecting the sensor(s) to the processor(s). The battery can include cells or cell groups in series. Each cell group can include a plurality of cells in parallel.

Conventional battery management systems for electric vehicles (EVs) and energy storage systems (ESS) rely primarily on external measurements such as surface temperature, voltage, and current, often using thermistors and thermal models to estimate the internal state of battery cells. These traditional approaches suffer from several limitations, including the following.

Lack of Direct Internal Measurement: Surface temperature readings and external sensors do not provide direct insight into the internal conditions of each cell, making it difficult to detect internal faults or unsafe operating conditions in a timely manner.

Model Dependency and Error Propagation: The accuracy of safety assessments is dependent on the precision of thermal and electrical models, which may not account for cell-to-cell variations or evolving cell conditions, leading to potential errors in determining the true state of safety.

Fragmented Data Sources: Safety parameters such as voltage and temperature are often derived from separate measurements, models, or algorithms, increasing the risk of inconsistent or erroneous safety determinations.

Inability to Detect Certain Failure Modes: Traditional systems may fail to detect certain failure modes, such as internal short circuits, until after a hazardous condition has developed.

Limited Adaptability and Scalability: Existing methods often require extensive training, calibration, or memory resources, and may not adapt well to variations across different battery packs or cell populations.

As a result, current battery management systems may not reliably ensure operation within a true safe operating area (SOA) for each individual cell, potentially compromising safety, reducing system efficiency, and increasing maintenance costs.

Examples of the technology disclosed herein address the need for improved detection and diagnosis of internal cell anomalies, connection and assembly defects, and thermal events in battery systems. Some such examples, address the limitations of traditional monitoring methods by enabling more direct, real-time, and data-driven assessment of battery health and safety, thereby enhancing reliability, safety, and sustainability in battery system operation and maintenance.

Some such examples, address these problems by introducing a method and system for battery management that utilizes measurement of complex impedance—preferably via electrochemical impedance spectroscopy (EIS)—to establish and monitor SOA limits across one or more frequencies for each cell (and in some examples for the battery). By analyzing one or more of the real and imaginary components of impedance, the system can in effect use complex impedance as an indication of internal cell conditions such as temperature, state of charge, and pressure, which are not readily accessible through traditional surface measurements or external sensors.

This approach enables the establishment of impedance limits for each cell, defining a safe operating area (SOA) that reflects the internal state of the battery. In some examples, the system compares live impedance measurements (or samples) to these limits, allowing for real-time detection of unsafe conditions or cell anomalies. When a cell operates outside its defined SOA as indicated by at least one component of the complex impedance at one or more frequencies, the system can initiate corrective actions such as alerting users, disconnecting the battery, or adjusting charging and discharging protocols.

By unifying safety and health parameters within a single measurement framework, the technology provides adaptive and data-driven battery management. This can result in improved safety, reliability, and longevity for battery systems, while also enabling more efficient maintenance and replacement strategies by identifying specific cells that require attention.

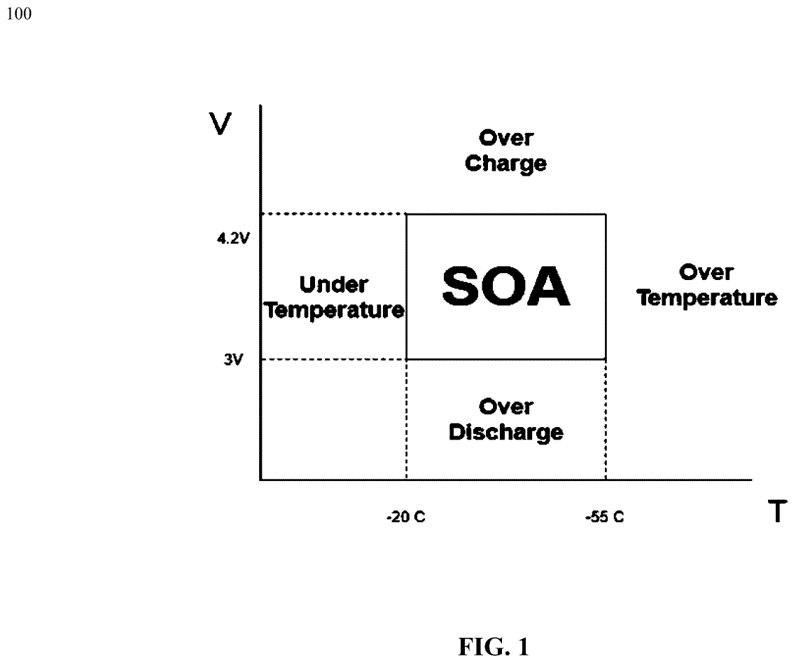

Referring to FIG. 1, the concept of safe operating area (SOA) 100 for a battery (or cells thereof) is illustrated, in accordance with examples of the technology disclosed herein. “SOA” refers to the range of conditions such as voltage (V), current (I), temperature (T), and state of charge (SoC), within which a battery can function reliably and safely without undue risk of damage, reduced performance, or safety hazards. Operating a battery outside its SOA can lead to overheating, accelerated degradation, reduced lifespan, or even dangerous events like thermal runaway or fire. Manufacturers can specify SOA limits to increase the likelihood of optimal performance and safety in applications like electric vehicles. FIG. 1 shows a simple SOA 100 based on voltage V and temperature T. Even allowing that different V-T SOAs can be used for different I and SoC, such an approach suffers from the drawbacks mentioned above.

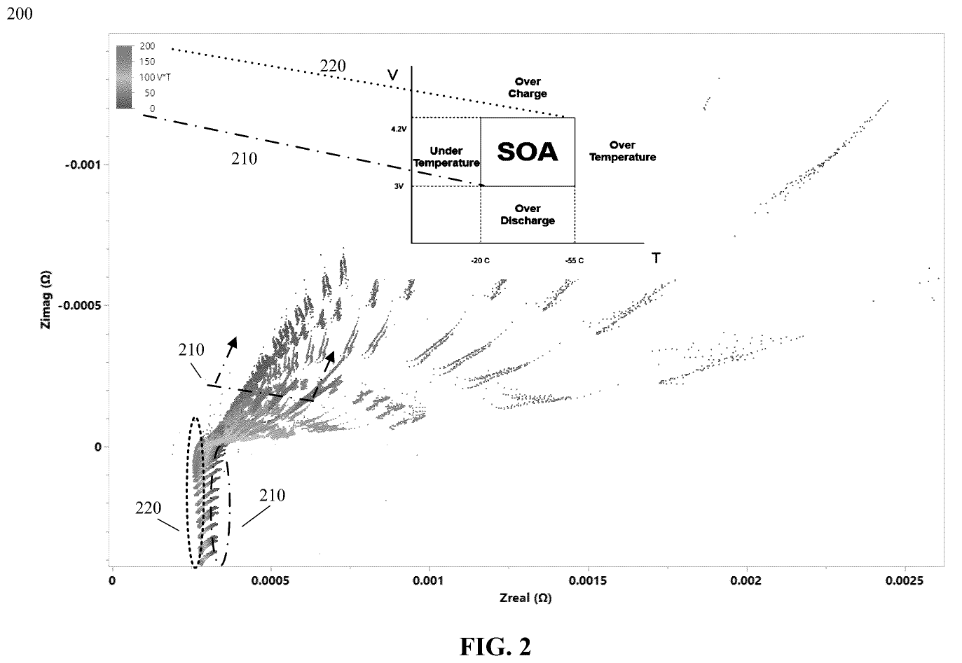

Referring to FIG. 2, and continuing to refer to FIG. 1 for context, a Nyquist plot 200 of cell complex impedance related to the product of voltage and temperature (low V*T 210, high V*T 220) is shown, in accordance with examples of the technology disclosed herein. The SOA 100 of FIG. 1 is shown, mapping low V*T 210 and high V*T 220 between regions of the SOA V-T plot and the Nyquist plot. The two SOA edge cases 210, 220 can be ascertained from complex impedance using EIS. The data for distinguishing the regions provides better focus for the higher frequencies.

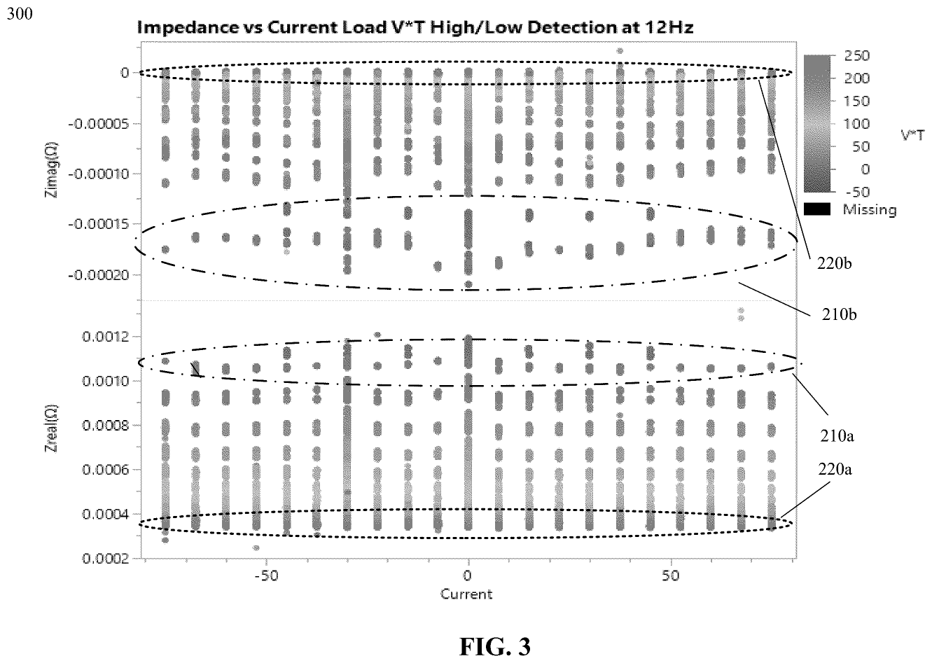

Referring to FIG. 3, and continuing to refer to prior figures for context, a plot 300 of each component of complex impedance versus current load for high V*T, low V*T of FIG. 2 at 12 Hz is presented, in accordance with examples of the technology disclosed herein. Across currents at this low frequency (12 Hz) and combination of V and T, both components (a=real, b=imaginary) of complex impedance for the two corners 210 220 of the SOA 100 of FIG. 1 can be discerned. In each case, the corresponding regions for the corners are approximate.

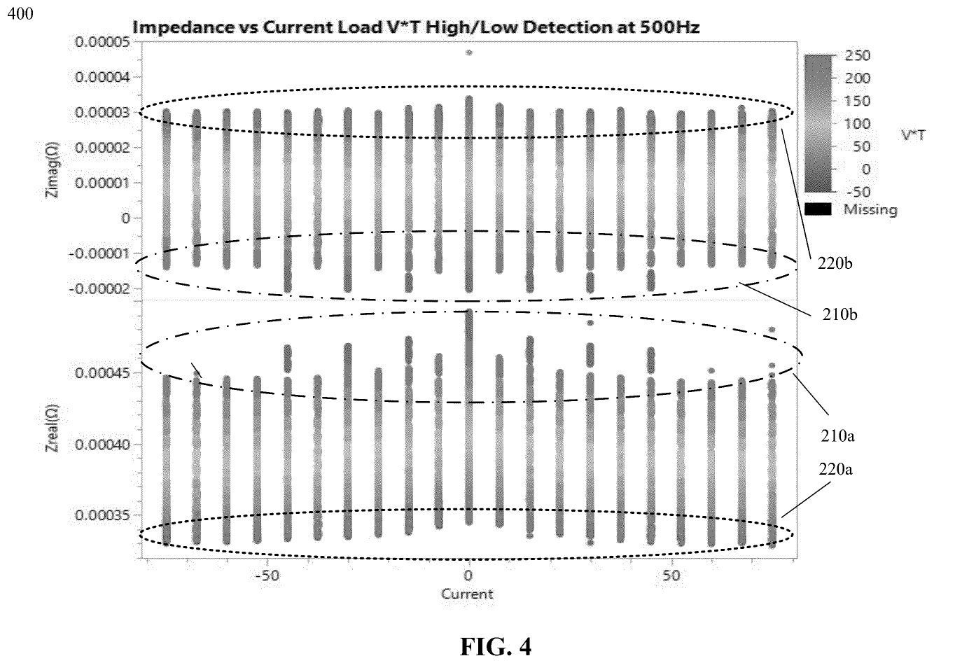

Referring to FIG. 4, and continuing to refer to prior figures for context, a plot 400 of each component of complex impedance versus current load for high V*T, low V*T of FIG. 2 at 500 Hz is presented, in accordance with examples of the technology disclosed herein. Across currents at this frequency (500 Hz), the two corners 210 220 of the SOA 100 of FIG. 1 can be identified. Note that 12 Hz and 500 Hz are examples only. In some examples, such as this one choosing a low and a high frequency is advisable, in part because if there is noise in the measurements the noise is less likely to impact both low frequencies and high frequencies at the same time. Further, SoC/V typically impacts the low frequencies while the temperature impacts slightly higher frequencies, so by choosing two frequencies quite apart, complementary (as opposed to duplicative information) can be gleaned.

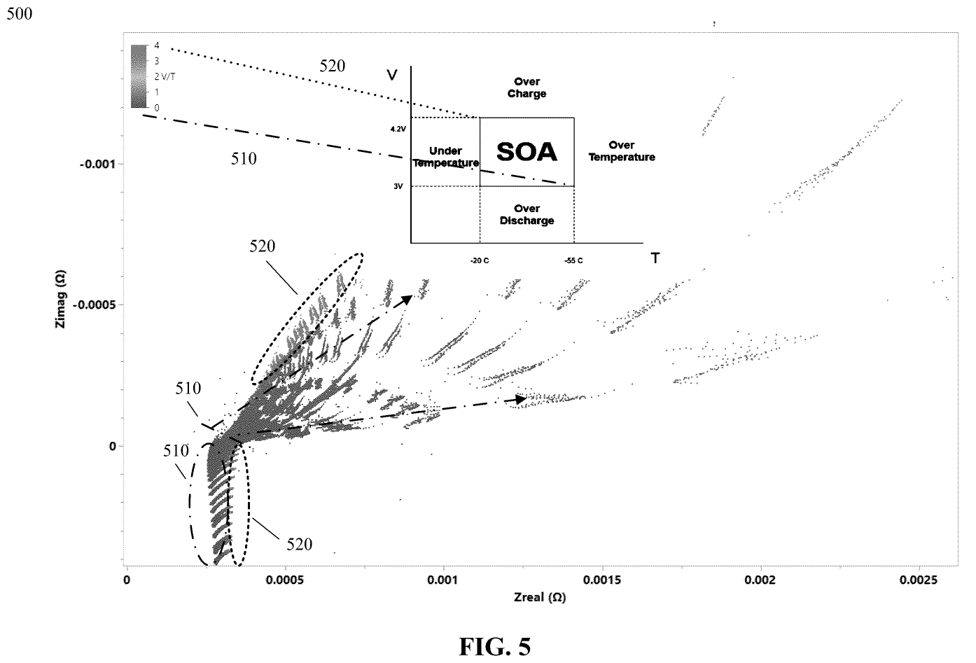

Referring to FIG. 5, and continuing to refer to prior figures for context, a Nyquist plot 500 of cell complex impedance related to the quotient of voltage and temperature (low V/T 510, high V/T 520) is shown, in accordance with examples of the technology disclosed herein. The SOA 100 of FIG. 1 is shown, mapping high V/T 520 and low V/T 510 between regions of the SOA V-T plot and the Nyquist plot. The data for distinguishing the regions provides better focus for the higher frequencies.

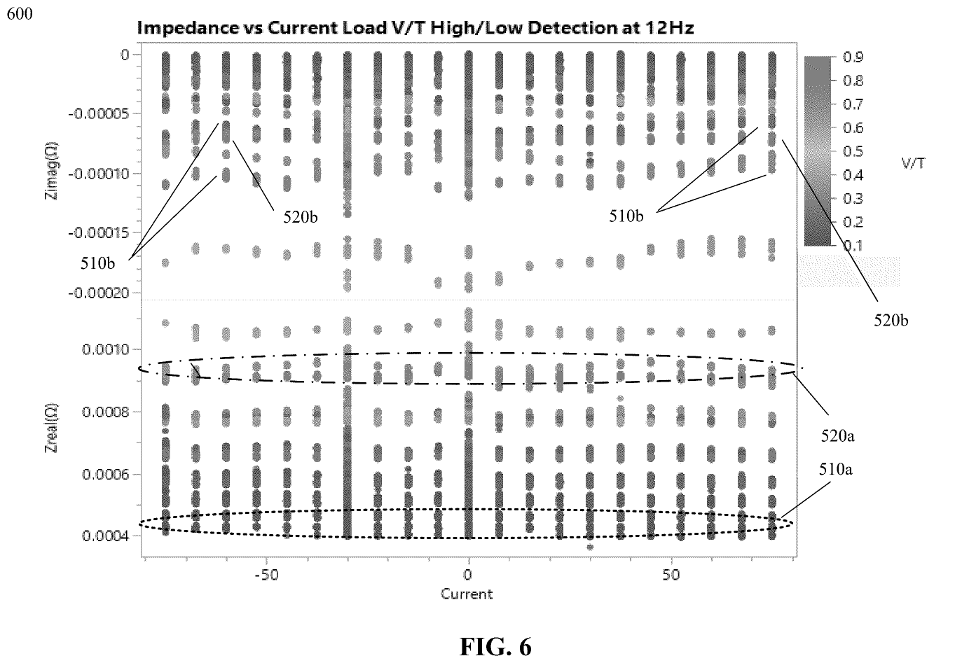

Referring to FIG. 6, and continuing to refer to prior figures for context, a plot 600 of each component of complex impedance versus current load for high V/T 510 and low V/T 520 of FIG. 5 at 12 Hz is presented, in accordance with examples of the technology disclosed herein. Across currents at this low frequency (12 Hz), while the regions between high V/T 510a and low V/T 520a cab be discerned for the real component of complex impedance across currents, it is difficult to establish distinct regions between high V/T 610a and low V/T 620b for the imaginary component where the high and low results are interspersed.

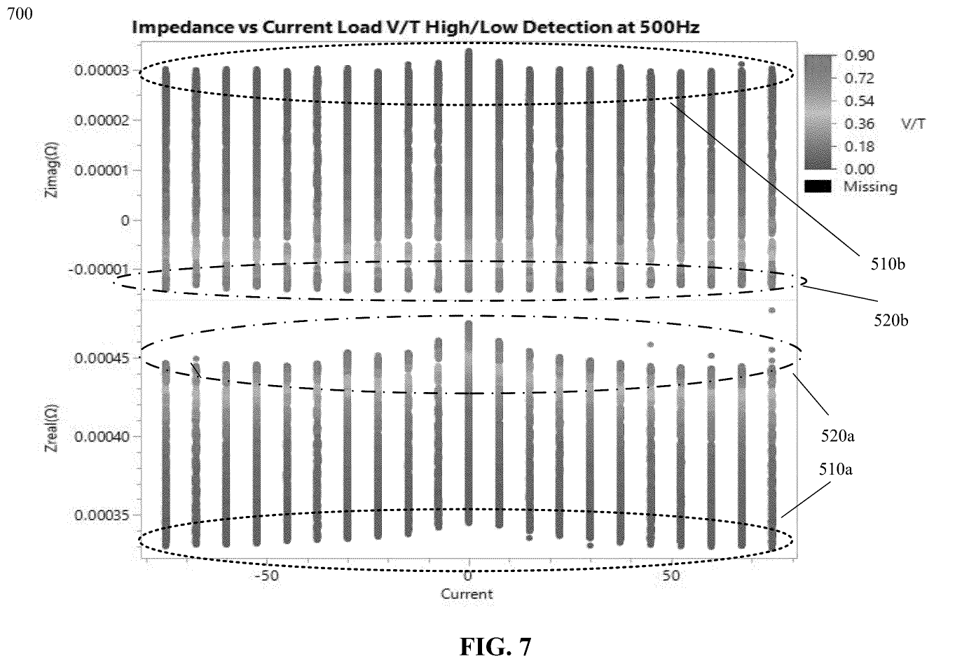

Referring to FIG. 7, and continuing to refer to prior figures for context, a plot 700 of each component of complex impedance versus current load for high V/T 510 and low V/T 520 of FIG. 5 at 500 Hz is presented, in accordance with examples of the technology disclosed herein. Across currents at this frequency (500 Hz), the two corners 510 520 of the SOA 100 of FIG. 1 can be identified.

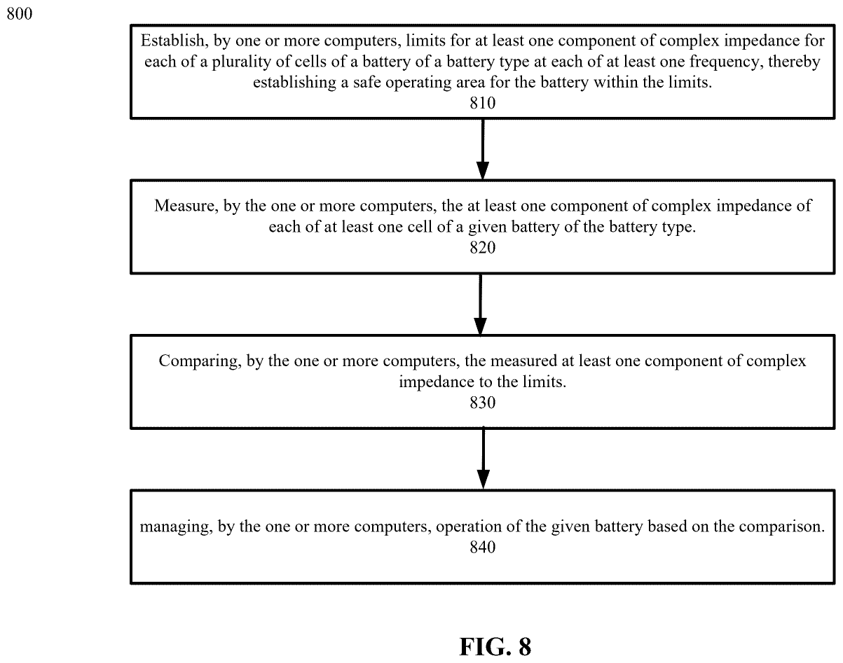

Referring to FIG. 8, and continuing to refer to prior figures for context, methods 800 of battery operation are illustrated, in accordance with examples of the technology disclosed herein. In such methods 800, one or more computers establish limits for at least one component of complex impedance for each of a plurality of cells of a battery of a battery type at each of at least one frequency, thereby establishing a safe operating area for the battery within the limits—Block 810.

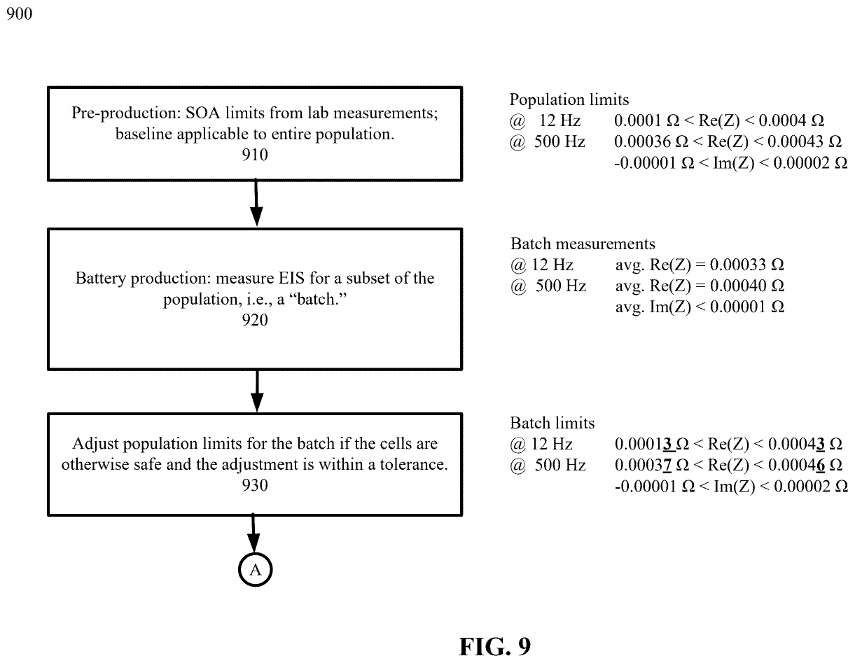

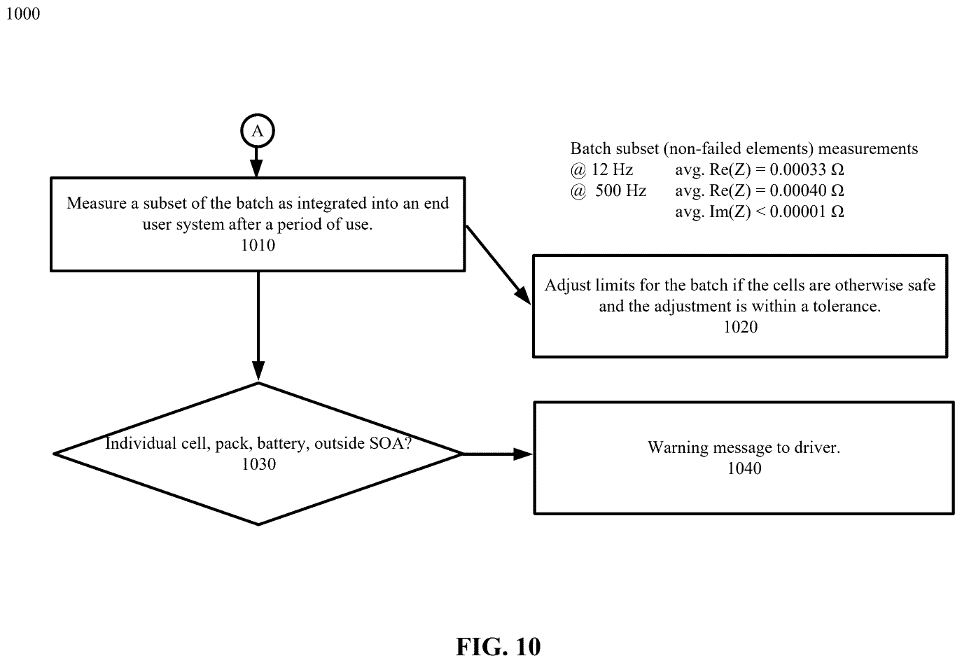

In a continuing example illustrated by FIG. 9 and FIG. 10, SOA complex impedance limits are established for a population of cells (of a certain cell type, to be assembled into batteries) via laboratory tests under various conditions—Block 910. Such tests can include cycling sample cells/batteries from the population at different voltages, currents, temperatures, etc. to observe the complex impedance corresponding to the limits of the safe operating arca. In the continuing example, limits on the real component of complex impedance R(Z) were established as 0.0001 Ω<Re(Z)<0.0004 Ω at 12 Hz. At such a low frequency, the imaginary component of complex impedance Im(Z) is less relevant. In the continuing example, limits were established at 500 Hz for R (Z) (0.00036 Ω<Re(Z)<0.00043 Ω) and Im(Z) (−0.00001 Ω<Im(Z)<0.00002 Ω).

In some examples, electrochemical analysis can be used to identify complex impedances where reactions, such as plating or electrolyte breakdown, may cause a battery to operate outside an SOA. In some examples, thermal models can be used to determine how much heat the battery generates under different loads and the complex impedance at which those conditions constitute unsafe operation. In some examples, governments, industry groups, or end user system manufacturers could set complex impedance limits that correspond to a variety of unsafe operation modes. In general, unsafe states can be mapped to characteristic complex impedances that are more reliably and directly measured than known methods of determining if a cell or battery in operating in an SOA. In some examples, complex impedance limits on SOA are established by the cell/battery vendor and provided to an integrator, e.g., in memory tables.

Examples of the technology disclosed herein offer a check on safety on each cell of a group of cells. Typically approaches are based on temperature measured only at a few locations in the pack and a “pre-production-for-all-packs” model to infer other locations (which typically does not take into consideration pack-to-pack variation of ineffective cooling) and on voltage on each cell block (this voltage typically does not change if a cell in a parallel cell block is disconnected, the impedance does).

In some examples after complex impedance limits on SOA are established for a population of cells, the at least one component of complex impedance can be measured for a subset of the population of cells (a “batch,” which may comprise cells intended for assembly into a same battery type)—Block 920. In the example of FIG. 9 and FIG. 10, during battery production, the batch of cells measured showed a slight difference from midrange of the baseline limits for Re (Z) at each of 12 Hz (avg. Re(Z)=0.00033 Ω) and 500 Hz (avg. Re(Z)=0.00040 Ω). In this case, establishing limits includes adjusting the population limits (to create batch limits) for Re(Z) at each of 12 Hz (0.00013 Ω<Re(Z)<0.00043 Ω) and 500 Hz (0.00037 Ω<Re(Z)<0.00046 Ω). Im(Z) at 500 Hz remains unchanged in this example. In some examples, limits can be set on how much the baseline impedance limits can be adjusted. Heuristics and data gathered across previous cells can be used in any adjustment.

Returning to FIG. 8, in such methods 800 the one or more computers measure the at least one component of complex impedance of each of at least one cell of a given battery of the battery type—Block 820.

In the continuing example, after a period of use with batteries comprising cells from the original population integrated into an end user system, the components of complex impedance are measured—Block 1010. For example, complex impedance may be measured and adjusted for mitigation of parasitic effect as explained in co-pending U.S. patent application Ser. No. 18/789,088. In the continuing example, the average measurements (for those cells not previously culled for any reason) for the batch fall within the range for SOA: at 12 Hz avg. Re(Z)=0.00033 Ω; at 500 Hz avg. Re(Z)=0.00040 Ω, avg. Im(Z)<0.00001 Ω—and hence were not adjusted per Block 1020. In some examples, population/batch statistics other than average can be used, e.g., standard deviation.

Returning to FIG. 8, in such methods 800 the one or more computers compare the measured at least one component of complex impedance to the limits—Block 830. In the continuing example, for a certain cell of the given battery, impedance was measured and adjusted for mitigation of parasitic effect as explained in co-pending U.S. patent application Ser. No. 18/789,088. The adjusted complex impedance was found to be outside the limits defining the SO—Block 1030.

In such methods 800, the one or more computers manage operation of the given battery based on the comparison—Block 840. In the continuing example, the computer implemented BMS in a vehicle sends a waring message to the vehicle driver—Block 1040.

In some examples, managing operation of the given battery includes one or more of alerting a user of a system comprising the given battery upon the comparison indicating operation of the given battery outside the safe operating area (as in the continuing example); disconnecting the given battery from a system comprising the given battery upon the comparison indicating operation of the given battery outside the safe operating arca; and controlling one or both of charging and discharging of the given battery upon the comparison indicating operation of the given battery outside the safe operating arca.

In some examples, establishing limits includes establishing battery-level limits for at least one component of complex impedance for the battery at each of at least one frequency, thereby establishing another bound on the safe operating area for the battery within the battery-level limits. In such examples, measuring includes measuring the at least one component of complex impedance of the battery; and comparing includes comparing the measured component(s) of complex impedance of the battery to the battery-level complex impedance limits.

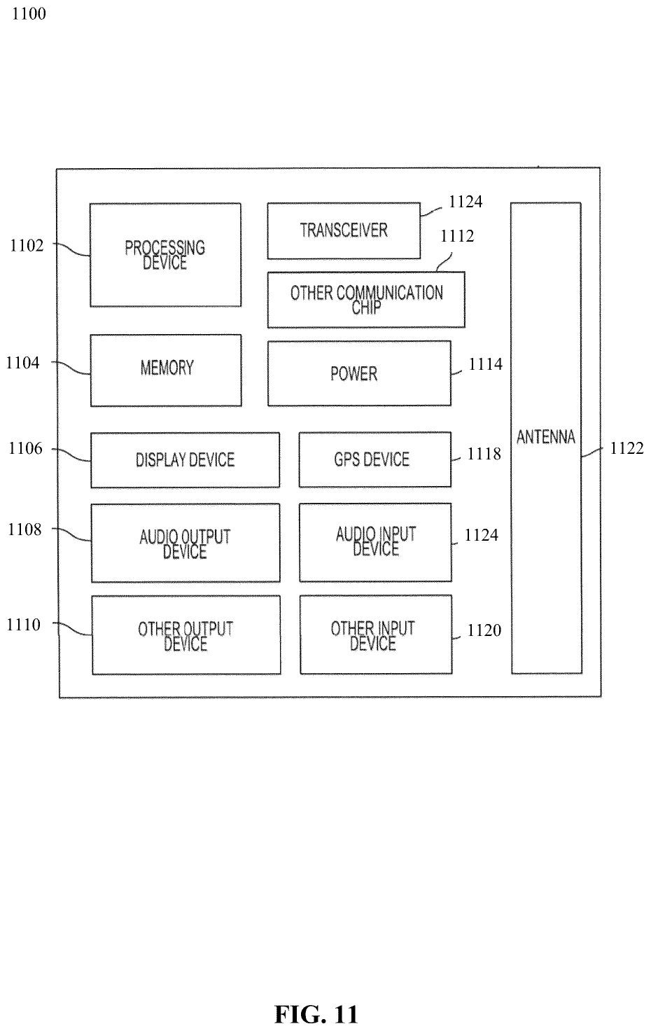

Examples of the present disclosure may be implemented into a system using any suitable hardware and/or software to configure as desired. Referring to FIG. 11, and continuing to refer to prior figures for context, FIG. 11 schematically illustrates a device 1100 that may serve as a computer/processor, in accordance with various examples. A number of components are illustrated in FIG. 11 as included in the device 1100, but any one or more of these components may be omitted or duplicated, as suitable for the application.

Additionally, in various examples, the device 1100 may not include one or more of the components illustrated in FIG. 11, but the device 1100 may include interface circuitry for coupling to the one or more components. For example, the device 1100 may not include a display device 1106, but may include display device interface circuitry (e.g., a connector and driver circuitry) to which a display device 1106 may be coupled. In another set of examples, the device 1100 may not include an audio input device 1124 or an audio output device 1108, but may include audio input or output device interface circuitry (e.g., connectors and supporting circuitry) to which an audio input device 1124 or audio output device 1108 may be coupled.

The device 1100 may include a transceiver 1124, in accordance with any of the examples disclosed herein, for managing communication along the bus when the device 1100 is coupled to the bus. The device 1100 may include a processing device 1102 (e.g., one or more processing devices), which may be included in the node transceiver or separate from the node transceiver. As used herein, the term “processing device” may refer to any device or portion of a device that processes electronic data from registers and/or memory to transform that electronic data into other electronic data that may be stored in registers and/or memory. The processing device 1102 may include one or more DSPs, ASICs, central processing units (CPUs), graphics processing units (GPUs), crypto-processors, or any other suitable processing devices. The device 1100 may include a memory 1104, which may itself include one or more memory devices such as volatile memory (e.g., dynamic random-access memory (DRAM)), non-volatile memory (e.g., read-only memory (ROM)), flash memory, solid state memory, and/or a hard drive.

In some examples, the memory 1104 may be employed to store a working copy and a permanent copy of programming instructions to cause the device 1100 to perform any suitable ones of the techniques disclosed herein. In some examples, machine-accessible media (including non-transitory computer-readable storage media), methods, systems, and devices for performing the above-described techniques are illustrative examples disclosed herein for communication over a two-wire bus. For example, a computer-readable media (e.g., the memory 1104) may have stored thereon instructions that, when executed by one or more of the processing devices included in the processing device 1102, cause the device 1100 to perform any of the techniques disclosed herein.

In some examples, the device 1100 may include another communication chip 1112 (e.g., one or more other communication chips). For example, the communication chip 1112 may be configured for managing wireless communications for the transfer of data to and from the device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some examples they might not.

The communication chip 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The one or more communication chips 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The one or more communication chips 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The one or more communication chips 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1112 may operate in accordance with other wireless protocols in other examples. The device 1100 may include an antenna 1122 to facilitate wireless communications and/or to receive other wireless communications (such as AM or FM radio transmissions).

In some examples, the communication chip 1112 may manage wired communications using a protocol other than the protocol for the bus described herein. Wired communications may include electrical, optical, or any other suitable communication protocols. Examples of wired communication protocols that may be enabled by the communication chip 1112 include Ethernet, controller area network (CAN), I2C, media-oriented systems transport (MOST), or any other suitable wired communication protocol.

As noted above, the communication chip 1112 may include multiple communication chips. For instance, a first communication chip 1112 may be dedicated to shorter-range wireless communications such as Wi-Fi or Bluetooth, and a second communication chip 1112 may be dedicated to longer-range wireless communications such as global positioning system (GPS), EDGE, GPRS, CDMA, WiMAX, LTE, EV-DO, or others. In some examples, a first communication chip 1112 may be dedicated to wireless communications, and a second communication chip 1112 may be dedicated to wired communications.

The device 1100 may include battery/power circuitry 1114. The battery/power circuitry 1114 may include one or more energy storage devices (e.g., batteries or capacitors) and/or circuitry for coupling components of the device 1100 to an energy source separate from the device 1100 (e.g., AC line power, voltage provided by a car battery, etc.).

The device 1100 may include a display device 1106 (or corresponding interface circuitry, as discussed above). The display device 1106 may include any visual indicators, such as a heads-up display, a computer monitor, a projector, a touchscreen display, a liquid crystal display (LCD), a light-emitting diode display, or a flat panel display, for example.

The device 1100 may include an audio output device 1108 (or corresponding interface circuitry, as discussed above). The audio output device 1108 may include any device that generates an audible indicator, such as speakers, headsets, or earbuds, for example.

The device 1100 may include an audio input device 1124 (or corresponding interface circuitry, as discussed above). The audio input device 1124 may include any device that generates a signal representative of a sound, such as microphones, microphone arrays, or digital instruments (e.g., instruments having a musical instrument digital interface (MIDI) output).

The device 1100 may include a GPS device 1118 (or corresponding interface circuitry, as discussed above). The GPS device 1118 may be in communication with a satellite-based system and may receive a location of the device 1100, as known in the art.

The device 1100 may include another output device 1111 (or corresponding interface circuitry, as discussed above). Examples of the other output device 1110 may include an audio codec, a video codec, a printer, a wired or wireless transmitter for providing information to other devices, or an additional storage device. Additionally, any suitable ones of the peripheral devices may be included in the other output device 1110.

The device 1100 may include another input device 1120 (or corresponding interface circuitry, as discussed above). Examples of the other input device 1120 may include an accelerometer, a gyroscope, an image capture device, a keyboard, a cursor control device such as a mouse, a stylus, a touchpad, a bar code reader, a Quick Response (QR) code reader, or a radio frequency identification (RFID) reader. Additionally, any suitable ones of the sensors or peripheral devices may be included in the other input device 1120.

Any suitable ones of the display, input, output, communication, or memory devices described above with reference to the device 1100 may serve as the peripheral device in system of the technology disclosed herein. Alternatively or additionally, suitable ones of the display, input, output, communication, or memory devices described above with reference to the device 1100 may be included in a host or a node (e.g., a main node or a sub node).

Although various ones of the examples discussed above describe the system of the technology disclosed herein in a vehicle setting, this is simply illustrative, and the system of the technology disclosed herein may be implemented in any desired setting. For example, in some examples, a “suitcase” implementation of the system of the technology disclosed herein may include a portable housing that includes the desired components of the system of the technology disclosed herein; such an implementation may be particularly suitable for portable applications, such as portable karaoke or entertainment systems.

Having thus described several aspects and examples of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the examples described herein.

Those skilled in the art will recognize or be able to ascertain using no more than routine experimentation, many equivalents to the specific examples described herein. It is, therefore, to be understood that the foregoing examples are presented by way of example only and that, within the scope of the appended claims and equivalents thereto, inventive examples may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more examples of the subject matter disclosed herein. These examples are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the examples introduced herein. The PHOSITA will also recognize that such equivalent constructions do not depart from the spirit and scope of the present disclosure, and that they may make various changes, substitutions, and alterations herein without departing from the spirit and scope of the present disclosure.

The above-described examples may be implemented in any of numerous ways. One or more aspects and examples of the present application involving the performance of processes or methods may utilize program instructions executable by a device (e.g., a computer, a processor, or other device) to perform, or control performance of, the processes or methods.

In this respect, various inventive concepts may be embodied as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium) encoded with one or more programs that, when executed on one or more computers or other processors, perform methods that implement one or more of the various examples described above.

The computer readable medium or media may be transportable, such that the program or programs stored thereon may be loaded onto one or more different computers or other processors to implement various ones of the aspects described above. In some examples, computer readable media may be non-transitory media.

Note that the activities discussed above with reference to the FIGURES which are applicable to any integrated circuit that involves signal processing (for example, gesture signal processing, video signal processing, audio signal processing, analog-to-digital conversion, digital-to-analog conversion), particularly those that can execute specialized software programs or algorithms, some of which may be associated with processing digitized real-time data.

In some cases, the teachings of the present disclosure may be encoded into one or more tangible, non-transitory computer-readable mediums having stored thereon executable instructions that, when executed, instruct a programmable device (such as a processor or DSP) to perform the methods or functions disclosed herein. In cases where the teachings herein are embodied at least partly in a hardware device (such as an ASIC, IP block, or SoC), a non-transitory medium could include a hardware device hardware-programmed with logic to perform the methods or functions disclosed herein. The teachings could also be practiced in the form of Register Transfer Level (RTL) or other hardware description language such as VHDL or Verilog, which can be used to program a fabrication process to produce the hardware elements disclosed.

In example implementations, at least some portions of the processing activities outlined herein may also be implemented in software. In some examples, one or more of these features may be implemented in hardware provided external to the elements of the disclosed figures, or consolidated in any appropriate manner to achieve the intended functionality. The various components may include software (or reciprocating software) that can coordinate in order to achieve the operations as outlined herein. In still other examples, these elements may include any suitable algorithms, hardware, software, components, modules, interfaces, or objects that facilitate the operations thereof.

Any suitably configured processor component can execute any type of instructions associated with the data to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, an FPGA, an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, processors may store information in any suitable type of non-transitory storage medium (for example, random access memory (RAM), read only memory (ROM), FPGA, EPROM, electrically erasable programmable ROM (EEPROM), etc.), software, hardware, or in any other suitable component, device, element, or object where appropriate and based on particular needs. Further, the information being tracked, sent, received, or stored in a processor could be provided in any database, register, table, cache, queue, control list, or storage structure, based on particular needs and implementations, all of which could be referenced in any suitable timeframe.

Any of the memory items discussed herein should be construed as being encompassed within the broad term ‘memory.’ Similarly, any of the potential processing elements, modules, and machines described herein should be construed as being encompassed within the broad term ‘microprocessor’ or ‘processor.’ Furthermore, in various examples, the processors, memories, network cards, buses, storage devices, related peripherals, and other hardware elements described herein may be realized by a processor, memory, and other related devices configured by software or firmware to emulate or virtualize the functions of those hardware elements.

Further, it should be appreciated that a computer may be embodied in any of a number of forms, such as a rack-mounted computer, a desktop computer, a laptop computer, or a tablet computer, as non-limiting examples. Additionally, a computer may be embedded in a device not generally regarded as a computer but with suitable processing capabilities, including a personal digital assistant (PDA), a smart phone, a mobile phone, an iPad, or any other suitable portable or fixed electronic device.

Also, a computer may have one or more input and output devices. These devices can be used, among other things, to present a user interface. Examples of output devices that may be used to provide a user interface include printers or display screens for visual presentation of output and speakers or other sound generating devices for audible presentation of output. Examples of input devices that may be used for a user interface include keyboards, and pointing devices, such as mice, touch pads, and digitizing tablets. As another example, a computer may receive input information through speech recognition or in other audible formats.

Such computers may be interconnected by one or more networks in any suitable form, including a local area network or a wide area network, such as an enterprise network, and intelligent network (IN) or the Internet. Such networks may be based on any suitable technology and may operate according to any suitable protocol and may include wireless networks or wired networks.

Computer-executable instructions may be in many forms, such as program modules, executed by one or more computers or other devices. Generally, program modules include routines, programs, objects, components, data structures, etc. that performs particular tasks or implement particular abstract data types. Typically, the functionality of the program modules may be combined or distributed as desired in various examples.

The terms “program” or “software” are used herein in a generic sense to refer to any type of computer code or set of computer-executable instructions that may be employed to program a computer or other processor to implement various aspects as described above. Additionally, it should be appreciated that according to one aspect, one or more computer programs that when executed perform methods of the present application need not reside on a single computer or processor, but may be distributed in a modular fashion among a number of different computers or processors to implement various aspects of the present application.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that convey relationship between the fields. However, any suitable mechanism may be used to establish a relationship between information in fields of a data structure, including through the use of pointers, tags or other mechanisms that establish relationship between data elements.

When implemented in software, the software code may be executed on any suitable processor or collection of processors, whether provided in a single computer or distributed among multiple computers.

Computer program logic implementing all or part of the functionality described herein is embodied in various forms, including, but in no way limited to, a source code form, a computer executable form, a hardware description form, a computer-implemented method with memory storing code/instructions therein, and various intermediate forms (for example, mask works, or forms generated by an assembler, compiler, linker, or locator). In an example, source code includes a series of computer program instructions implemented in various programming languages, such as an object code, an assembly language, or a high-level language such as OpenCL, RTL, Verilog, VHDL, Fortran, C, C++, JAVA, or HTML for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

In some examples, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, examples may be constructed in which acts are performed in an order different than illustrated, which may include performing some acts simultaneously, even though shown as sequential acts in illustrative examples.

### Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims: “comprise,” “comprising,” and the like are to be construed in an inclusive sense, as opposed to an exclusive or exhaustive sense; that is to say, in the sense of “including, but not limited to.” “Connected,” “coupled,” or any variant thereof, means any connection or coupling, either direct or indirect, between two or more elements. The coupling or connection between the elements can be physical, logical, or a combination thereof. “Herein,” “above,” “below,” and words of similar import, when used to describe this specification shall refer to this specification as a whole and not to any particular portions of this specification. “Or,” in reference to a list of two or more items, covers all of the following interpretations of the word: any of the items in the list, all of the items in the list, and any combination of the items in the list. The singular forms “a,” “an” and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present) depend on the specific orientation of the apparatus described and illustrated. The subject matter described herein may assume various alternative orientations. Accordingly, these directional terms are not strictly defined and should not be interpreted narrowly.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one example, to A only (optionally including elements other than B); in another example, to B only (optionally including elements other than A); in yet another example, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one example, to at least one, optionally including more than one, A, with no B present (and optionally including elements other than B); in another example, to at least one, optionally including more than one, B, with no A present (and optionally including elements other than A); in yet another example, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112 (f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular examples described above. Various modifications, equivalent processes, as well as numerous structures to which the present invention may be applicable, will be readily apparent to those skilled in the art to which the present invention is directed upon review of the present disclosure.

It should be understood that the detailed description and specific examples, while indicating examples of the systems and methods are intended for purposes of illustration only and are not intended to limit the scope. These and other features, aspects, and advantages of the systems and methods of the present invention can be better understood from the description, appended claims or aspects, and accompanying drawings. It should be understood that the Figures are merely illustrative and are not drawn to scale. It should also be understood that the same reference numerals are used throughout the figures to indicate the same or similar parts.

Other variations to the disclosed examples can be understood and effected by those skilled in the art in practicing the disclosure, from a study of the drawings, the disclosure, and the appended aspects or claims. In the aspects or claims, the word “comprising” does not exclude other elements or steps, and the indefinite article “a” or “an” does not exclude a plurality. The mere fact that certain measures are recited in mutually different dependent aspects or claims does not indicate that a combination of these measures cannot be used to advantage. Any reference signs in the claims should not be construed as limited the scope.

What is claimed is:

1. A computer-implemented battery management method, comprising:
establishing, by one or more computers, limits for at least one component of complex impedance for each of a plurality of cells of a battery of a battery type at each of at least one frequency, thereby establishing a safe operating area for the battery within the limits;
measuring, by the one or more computers, the at least one component of complex impedance of each of at least one cell of a given battery of the battery type;
comparing, by the one or more computers, the measured at least one component of complex impedance to the limits; and
managing, by the one or more computers, operation of the given battery based on the comparison.

2. The method of claim 1, wherein measuring comprises measuring using electrochemical impedance spectroscopy (EIS).

3. The method of claim 1, wherein managing comprises:
alerting a user of a system comprising the given battery upon the comparison indicating operation of the given battery outside the safe operating area;
disconnecting the given battery from a system comprising the given battery upon the comparison indicating operation of the given battery outside the safe operating area; and
controlling one or both of charging and discharging of the given battery upon the comparison indicating operation of the given battery outside the safe operating area.

4. The method of claim 1, wherein:
establishing limits comprises establishing baseline limits based on a population of cells to be assembled into a group of batteries including the given battery; and
comparing comprises comparing the measured at least one component of complex impedance to the baseline limits.

5. The method of claim 1, wherein:
establishing limits comprises:
establishing baseline limits based on a population of cells to be assembled into a group of batteries including the given battery, and
adjusting the baseline limits, within a preset tolerance, for a subset of the population; and
comparing comprises comparing the measured at least one component of complex impedance to the adjusted limits.

6. The method of claim 1, wherein:
establishing limits further comprises establishing battery-level limits for at least one component of complex impedance for the battery at each of at least one frequency, thereby establishing another bound on the safe operating area for the battery within the battery-level limits;
measuring further comprises measuring the at least one component of complex impedance of the battery; and
comparing further comprises comparing the measured at least one component of complex impedance of the battery to the battery-level complex impedance limits.

7. A battery management system comprising:
a processor; and
a memory storing instructions that, when executed by the processor, cause the processor to:
establish limits for at least one component of complex impedance for each of a plurality of cells of a battery at each of at least one frequency, thereby establishing a safe operating area for the battery within the limits;
measure the at least one component of complex impedance of each of at least one cell of a given battery;
compare the measured at least one component of complex impedance to the limits; and
manage operation of the given battery based on the comparison.

8. The system of claim 7, wherein measuring comprises measuring using electrochemical impedance spectroscopy (EIS).

9. The system of claim 7, wherein managing comprises:
alerting a user of a system comprising the given battery upon the comparison indicating operation of the given battery outside the safe operating area;
disconnecting the given battery from a system comprising the given battery upon the comparison indicating operation of the given battery outside the safe operating area; and
controlling one or both of charging and discharging of the given battery upon the comparison indicating operation of the given battery outside the safe operating area.

10. The system of claim 7, wherein:
establishing limits comprises establishing baseline limits based on a population of cells to be assembled into a group of batteries including the given battery; and
comparing comprises comparing the measured at least one component of complex impedance to the baseline limits.

11. The system of claim 7, wherein:
establishing limits comprises:
establishing baseline limits based on a population of cells to be assembled into a group of batteries including the given battery, and
adjusting the baseline limits, within a preset tolerance, for a subset of the population; and
comparing comprises comparing the measured at least one component of complex impedance to the adjusted limits.

12. A non-transitory computer-readable medium storing instructions that, when executed by a processor, cause the processor to:
establish limits for at least one component of complex impedance for each of a plurality of cells of a battery at each of at least one frequency, thereby establishing a safe operating area for the battery within the limits;
measure the at least one component of complex impedance of each of at least one cell of a given battery;
compare the measured at least one component of complex impedance to the limits; and
manage operation of the given battery based on the comparison.

13. The non-transitory computer-readable medium of claim 12, wherein measuring comprises measuring using electrochemical impedance spectroscopy (EIS).

14. The non-transitory computer-readable medium of claim 12, wherein managing comprises:
alerting a user of a system comprising the given battery upon the comparison indicating operation of the given battery outside the safe operating area;
disconnecting the given battery from a system comprising the given battery upon the comparison indicating operation of the given battery outside the safe operating area; and
controlling one or both of charging and discharging of the given battery upon the comparison indicating operation of the given battery outside the safe operating area.

15. The non-transitory computer-readable medium of claim 12, wherein:
establishing limits comprises establishing baseline limits based on a population of cells to be assembled into a group of batteries including the given battery; and
comparing comprises comparing the measured at least one component of complex impedance to the baseline limits.

16. The non-transitory computer-readable medium of claim 12, wherein:
establishing limits comprises:
establishing baseline limits based on a population of cells to be assembled into a group of batteries including the given battery, and
adjusting the baseline limits, within a preset tolerance for a subset of the population; and
comparing comprises comparing the measured at least one component of complex impedance to the adjusted limits.

17. A battery system comprising:
a battery including a plurality of cells;
a measurement circuit configured to measure at least one component of complex impedance of each of at least one cell of the battery at each of at least one frequency; and
a controller configured to:
establish limits for the at least one component of complex impedance for each of the plurality of cells at each of the at least one frequency, thereby establishing a safe operating area for the battery within the limits;
compare the measured at least one component of complex impedance to the limits; and
manage operation of the battery based on the comparison.

18. The battery system of claim 17, wherein the measurement circuit is configured to perform electrochemical impedance spectroscopy (EIS).

19. The battery system of claim 17, wherein the controller is further configured to:
alert a user of a system comprising the battery upon the comparison indicating operation of the battery outside the safe operating area;
disconnect the battery from a system comprising the battery upon the comparison indicating operation of the battery outside the safe operating area; and
control one or both of charging and discharging of the battery upon the comparison indicating operation of the battery outside the safe operating area.

20. The battery system of claim 17, wherein:
the controller is configured to:
establish baseline limits based on a population of cells to be assembled into a group of batteries including the battery,
adjust the baseline limits, within a preset tolerance for a subset of the population, and
compare the measured at least one component of complex impedance to the adjusted limits.
